(19) United States
(12) Patent Application Publication
(10) Pub. No.: US 2025/0143055 A1
(43) Pub. Date: May 1, 2025

(54) Light-Emitting Device And Display Apparatus

(71) Applicant: Sony Group Corporation, Tokyo (JP)

(72) Inventors: Shin Akasaka, Kanagawa (JP); Soya Araki, Kanagawa (JP)

(73) Assignee: Sony Group Corporation, Tokyo (JP)

(21) Appl. No.: 18/836,841

(22) PCT Filed: Nov. 25, 2022
(86) PCT No.: PCT/JP2022/043462

§ 371 Date: Aug. 8, 2024

(30) Foreign Application Priority Data
Mar. 3, 2022 (JP) 2022-032438
Apr. 28, 2022 (JP) 2022-075412

(51) Int. Cl. H10H 29/49

(52) U.S. Cl. CPC H10H 29/49

(57) ABSTRACT

Provided is a light-weight optical device exhibiting excellent light-emitting performance. The light-emitting device includes multiple light source units and a relay member. The multiple light source units each include a light source board extending in a first direction and multiple light sources arranged along the first direction on the light source board. The relay member is electrically coupled to each of the multiple light source units.

### TECHNICAL FIELD

The present disclosure relates to a light-emitting device suitable for a surface light source, and a display apparatus that displays images using illumination light emitted by the light-emitting device.

### BACKGROUND ART

Heretofore, a light source device including a light emitting diode (LED) as a light source has been used as a backlight of a liquid crystal display apparatus for example (see, for example, Patent Literature 1 and Patent Literature 2).

### CITATION LIST

### Patent Literature

PTL 1: Japanese Unexamined Patent Application Publication No. 2012-203997
PTL 2: International Publication No. WO 2020/039721

### SUMMARY OF THE INVENTION

Meanwhile, in recent years, there has been a demand for a light-emitting device that includes a plurality of light sources highly integrated and that makes it possible to achieve a higher-definition light-emission luminance distribution.

Therefore, a light-emitting device that makes it possible to exhibit excellent light emission performance and a display apparatus including the same are desired.

A light-emitting device according to an embodiment of the present disclosure includes multiple light source units and a relay member. The multiple light source units each include a light source board extending in a first direction and multiple light sources arranged in a row along the first direction on the light source board. The relay member is electrically coupled to each of the multiple light source units.

In the light-emitting device according to an embodiment of the present disclosure, it is possible to finely adjust the arrangement positions for multiple light source units, facilitating optimization of the arrangement position of each light source. This is advantageous for weight reduction.

### BRIEF DESCRIPTION OF DRAWINGS

FIG. 1A is a first perspective view of a light-emitting device according to a first embodiment of the present disclosure as viewed from a first direction.

FIG. 1B is a second perspective view of the light-emitting device illustrated in FIG. 1A as viewed from a second direction.

FIG. 2 is a plane view illustrating a planar configuration of the light-emitting device illustrated in FIG. 1A.

FIG. 3 is a cross-sectional view illustrating a cross-sectional configuration of a part of the light-emitting device illustrated in FIG. 1.

FIG. 4 is an enlarged cross-sectional view illustrating a configuration example of a light source illustrated in FIG. 1.

FIG. 5 is an enlarged cross-sectional view illustrating a configuration example of a wavelength conversion sheet illustrated in FIG. 1.

FIG. 6 is a plan view illustrating a configuration example of a light source device according to a first modification example of the first embodiment.

FIG. 7 is a perspective view of an external appearance of a display apparatus according to a second embodiment of the present disclosure.

FIG. 8 is an exploded perspective view of a body illustrated in FIG. 7.

FIG. 9 is an exploded perspective view of a panel module illustrated in FIG. 8.

FIG. 10 is a schematic plan view illustrating a planar configuration example of the panel module illustrated in FIG. 8.

FIG. 11 is a schematic plan view illustrating a planar configuration example of a panel module according to a first modification example of the second embodiment.

FIG. 12 is a schematic plan view illustrating a planar configuration example of a panel module according to a second modification example of the second embodiment.

FIG. 13 is a schematic plan view illustrating a planar configuration example of a panel module according to a third modification example of the second embodiment.

FIG. 14 is a cross-sectional view illustrating another configuration example of the light-emitting device according to a first modification example of the present disclosure.

FIG. 15 is a cross-sectional view illustrating another configuration example of the light-emitting device according to a second modification example of the present disclosure.

FIG. 16 is a cross-sectional view illustrating another configuration example of the light-emitting device according to a third modification example of the present disclosure.

FIG. 17 is a cross-sectional view illustrating another configuration example of the light-emitting device according to a fourth modification example of the present disclosure.

FIG. 18 is a cross-sectional view illustrating another configuration example of the light-emitting device according to a fifth modification example of the present disclosure.

FIG. 19 is a cross-sectional view illustrating another configuration example of the light-emitting device according to a sixth modification example of the present disclosure.

FIG. 20 is a cross-sectional view illustrating another configuration example of the light-emitting device according to a seventh modification example of the present disclosure.

FIG. 21 is a cross-sectional view illustrating a detailed configuration of an electrically conductive material layer of the light-emitting device illustrated in FIG. 20.

FIG. 22A is a first cross-sectional view illustrating a process of forming the electrically conductive material layer illustrated in FIG. 21.

FIG. 22B is a second cross-sectional view illustrating the process of forming the electrically conductive material layer illustrated in FIG. 21.

FIG. 22C is a third cross-sectional view illustrating the process of forming the electrically conductive material layer illustrated in FIG. 21.

FIG. 23 is a cross-sectional view illustrating a detailed configuration of an electrically conductive material layer according to a first modification example of the light-emitting device illustrated in FIG. 20.

FIG. 24A is a first cross-sectional view illustrating a process of forming the electrically conductive material layer illustrated in FIG. 23.

FIG. 24B is a second cross-sectional view illustrating the process of forming the electrically conductive material layer illustrated in FIG. 23.

FIG. 24C is a third cross-sectional view illustrating the process of forming the electrically conductive material layer illustrated in FIG. 23.

FIG. 25 is a cross-sectional view illustrating a detailed configuration of an electrically conductive material layer according to a second modification example of the light-emitting device illustrated in FIG. 20.

FIG. 26 is a schematic plan view schematically illustrating an exemplary positional relation between bumps of the respective light-emitting devices and exposed part of a wire that are illustrated in FIGS. 23 and 25.

FIG. 27 is a cross-sectional view illustrating another configuration example of the light-emitting device according to an eighth modification example of the disclosure.

FIG. 28 is a cross-sectional view illustrating another configuration example of the display apparatus according to a ninth modification example of the present disclosure.

### MODES FOR CARRYING OUT THE INVENTION

In the following, embodiments of the present disclosure are described in detail with reference to the drawings. It is to be noted that the description is made in the following order.
1. First Embodiment (Light-emitting Device)
2. Second Embodiment (Liquid Crystal Display Apparatus)
3. Other Modification Examples

### 1. First Embodiment

### 1.1 Configuration

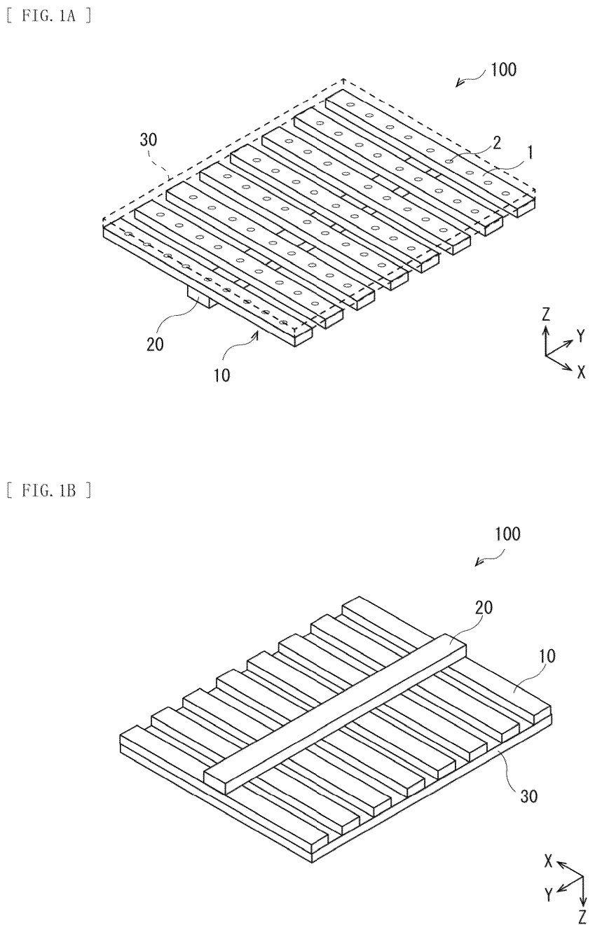

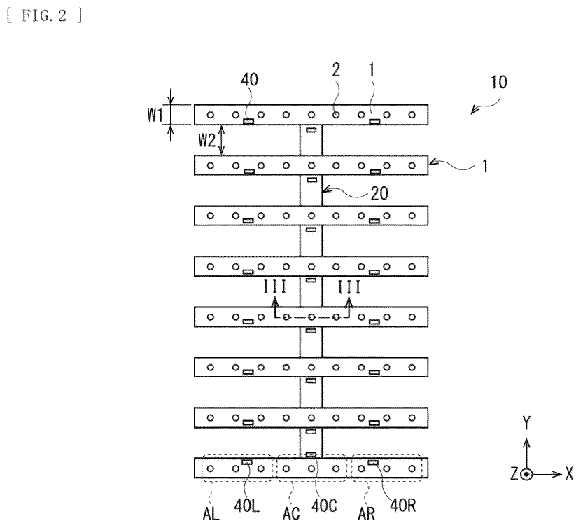

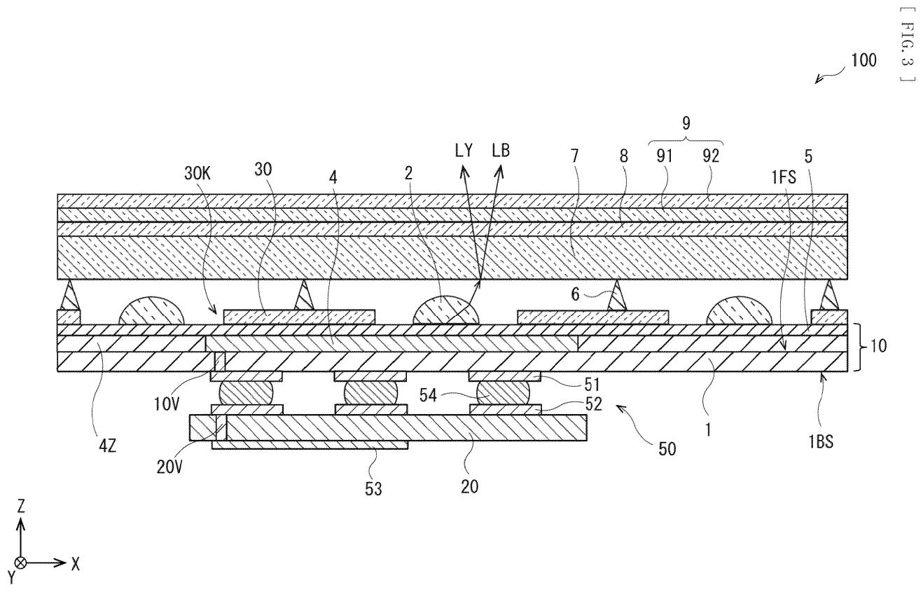

FIGS. 1A and 1B are perspective views each illustrating a configuration example of a light-emitting device 100 according to a first embodiment of the present disclosure. FIGS. 1A and 1B illustrate the light-emitting device 100 viewed from exactly opposite directions to each other. FIG. 2 is a plane view illustrating a planar configuration example of the light-emitting device 100 illustrated in FIG. 1. Further, FIG. 3 is an enlarged cross-sectional view illustrating a cross-sectional configuration example of a part of the light-emitting device 100 illustrated in FIG. 1. It is to be noted that FIG. 3 illustrates a cross-section taken along an arrow direction along a III-III cutting line indicated in FIG. 2. The light-emitting device 100 is suitable for a surface light source and is used, for example, as a direct backlight mounted in a liquid crystal display apparatus.

The light-emitting device 100 includes, for example, multiple light source units 10, a relay board 20, and a flexible film 30. The multiple light source units 10 each extend in an X-axis direction and are arranged to be aligned in a row in a Y-axis direction. In contrast, the relay board 20 extends, for example, in the Y-axis direction and is mechanically joined to each of the multiple light source units 10. The relay board 20 is also electrically coupled to each of the multiple light source units 10 with multiple coupling portions 50.

In the present embodiment, the X-axis direction corresponds to a longitudinal direction of the light source unit 10, the Y-axis direction corresponds to a lateral direction of the light source unit 10, and a Z-axis direction corresponds to a thickness direction of the light source unit 10. The X-axis direction, the Y-axis direction, and the Z-axis direction are perpendicular to each other.

As illustrated in FIG. 1A, each light source unit 10 includes a light source board 1 and multiple light sources 2. As illustrated in FIG. 3, the light source board 1 has a front surface 1FS and a back surface 1BS on an opposite side to the front surface 1FS in the thickness direction (the Z-axis direction). The multiple light sources 2 are provided on the front surface 1FS of the light source board 1 (FIG. 3). The multiple light sources 2 are aligned at predetermined intervals in, for example, one row along the X-axis direction, which is the longitudinal direction of the light source board 1. Further, the flexible film 30 extends along an XY plane and is provided on a front surface 1FS side of the light source board 1 so as to entirely cover the multiple light source units 10. The multiple light source units 10 may be fixed to the flexible film 30 by, for example, bonding. The relay board 20 is provided on a back surface 1BS side of the light source board 1. As illustrated in FIG. 2, the light-emitting device 100 includes driving elements 40. The driving elements 40 may be provided, for example, on the light source board 1 of each light source unit 10, or may be provided on the relay board 20. As illustrated in FIG. 3, the light-emitting device 100 may further include spacers 6, a diffusion sheet 7, a wavelength conversion sheet 8, and an optical sheet group 9.

### (Light Source Unit 10)

As illustrated in FIGS. 1A and 1B and FIG. 2, the multiple light source units 10 is preferably aligned spaced apart from each other along the Y-axis direction, for example. In particular, as illustrated in FIG. 2, a width W1, which is a dimension of the light source unit 10 in the Y-axis direction, is preferably narrower than an interval W2 between two adjacent ones of the light source units 10. A reason for this is that it is possible to reduce a constituent materials of the light source board 1 and the like, achieving weight reduction. It is to be noted that, in the examples illustrated in FIGS. 1A and 1B and FIG. 2, eight light source units 10 are coupled to one relay board 20; however, the present disclosure is not limited thereto. Seven or less light source units 10 may be coupled to one relay board 20, or nine or more light source units 10 may be coupled to one relay board 20.

As illustrated in FIG. 3, the light source unit 10 includes the light source board 1, the multiple light sources 2, wires 4, an insulating layer 4Z, and a resin layer 5. The light source board 1 is, for example, a resin film-like member having an electrically insulating property. The light source board 1 preferably has flexibility. As the light source board 1, a resin-made film including, for example, polyimide (PI), polyethylene terephthalate (PET), polycarbonate (PC), polyethylene naphthalate (PEN), polyetherimide (PEI), liquid crystal polymer (LCP), or fluororesin may be used. Alternatively, as the light source board 1, an insulating resin layer including, for example, polyimide or an epoxy-based resin and formed on a surface of a metal-base substrate including, for example, aluminum (Al) may be used. Still alternatively, as the light source board 1, a film base material including a glass-containing resin, such as a glass epoxy resin typified by FR4 or a glass composite resin typified by CEM3, may be used. The multiple wires 4 provided in the insulating layer 4Z and the multiple light sources 2 are mounted on the front surface 1FS of the light source board 1. Further, multiple wires 51 are formed on the back surface 1BS of the light source board 1. The multiple wires 51 are electrically coupled to the wires 4 via, for example, a via 10V. It is to be noted that the via 10V may be formed by forming a via hole by selectively etching down a predetermined area of the back surface 1BS of the light source board 1 by, for example, laser processing, and then filling the via hole with an electrically conductive material. At this time, the wires 4 formed on the front surface 1FS serve as etching stoppers.

### (Light Source 2 and Wire 4)

The multiple light sources 2 are provided on the front surface 1FS of the light source board 1. As described above, the multiple light sources 2 are arranged at the predetermined intervals in one row along the X-axis direction, which is an extending direction of the light source board 1, as illustrated in FIG. 2, for example. It is to be noted that the interval between the multiple light sources 2 is not limited to a constant interval, and may be set to any interval as desired. Alternatively, multiple rows of the light sources 2 may be provided on one light source board 1 such that the rows of the multiple light sources 2 aligned in the X-axis direction are adjacent to each other in the Y-axis direction. On the front surface 1FS of the light source board 1, the multiple wires 4 having predetermined pattern shapes are formed so that light-emission control is enabled to be independently performed for each light source 2 or for two or more light sources 2. The multiple wires 4 enables local light-emission control (local dimming) of the multiple light sources 2 to be performed. In the light-emitting device 100, the driving elements 40 control light-emission strength and lighting timing for each unit area A (AL, AC, and AR) indicated by a broken line in FIG. 2, for example. The driving elements 40 are driving ICs that drive the respective light sources 2, that is, driving ICs that turn on and turn off the light sources 2. The driving elements 40 are preferably provided on at least one of the relay board 20 or the light source board 1. In the configuration example of FIG. 2, one driving element 40L and one driving element 40R are provided on the light source board 1, and a driving element 40C is provided on the relay board 20. In the configuration example of FIG. 2, the light sources 2 provided in the unit area AL are coupled to the driving element 40L by the wires 4, the light sources 2 provided in the unit area AC are coupled to the driving element 40C by the wires 4, and the light sources 2 provided in the unit area AR are coupled to the driving element 40R by the wires 4. The driving element 40L drives, for example, three light sources 2 provided in the unit area AL among the multiple light sources 2 provided on the light source board 1. The driving element 40C drives, for example, three light sources 2 provided in the unit area AC among the multiple light sources 2 provided on the light source board 1. The driving element 40R drives, for example, three light sources 2 provided in the unit area AR among the multiple light sources 2 provided on the light source board 1. It is to be noted that, in the example illustrated in FIG. 2, three light sources 2 are arranged in one unit area A; however, the present disclosure is not limited thereto. The number of light sources 2 included in one unit area A may be one or two, or may be four or more.

The wire 4 is formed by bonding a copper foil to the light source board 1 and then patterning the copper foil by a photolithography method, for example. Alternatively, the wire 4 may be formed by forming a metal film on the light source board 1 by plating or a vacuum film forming technology, and then patterning the metal film by a photolithography method. Still alternatively, the wire 4 may be formed by a printing method such as screen printing or an inkjet method. Examples of a constituent material of the wire 4 include copper (Cu), aluminum (Al), silver (Ag), and an alloy thereof.

### (Resin Layer 5)

The resin layer 5 is, for example, a white resist layer. The resin layer 5 has a relatively high reflectance with respect to light from the light source 2 and light with a wavelength converted by the wavelength conversion sheet 8. Examples of the white resist include inorganic materials such as titanium oxide (TiO₂) fine particles and barium sulfate (BaSO₄) fine particles, and organic materials such as porous acrylic resin fine particles having numerous pores for light-scattering and polycarbonate resin fine particles. As a constituent material of the resin layer 5, an epoxy-based resin may be also used. Further, the resin layer 5 may include a resin that contains fine particles of an inorganic material such as titanium oxide (TiO₂) fine particles and barium sulfate (BaSO₄) fine particles. The flexible film 30 is bonded to an area of a front surface of the resin layer 5 other than the area where the light sources 2 are provided.

### (Details of Light Source 2)

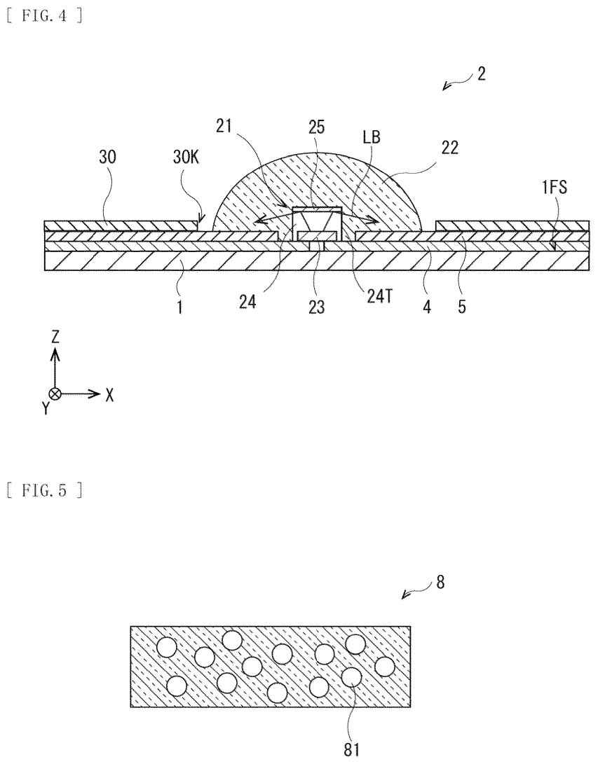

FIG. 4 is an enlarged cross-sectional view illustrating a configuration example of the light source 2 illustrated in FIG. 1. It is to be noted that FIG. 4 also illustrates the flexible film 30. As illustrated in FIG. 4, the light source 2 is a so-called direct-potting type light source, and includes a light-emitting element 21 and a sealing lens 22. The light-emitting element 21 includes, for example, a semiconductor layer 23 including a light-emitting body, and a reflective layer 25 disposed so as to be opposed to the semiconductor layer 23 in the Z-axis direction with the transparent layer 24 interposed therebetween.

A transparent layers 24 includes, for example, sapphire or silicon carbide (SIC). The semiconductor layer 23 is formed by, for example, sequentially stacking an n-type semiconductor layer, an active layer, and a p-type semiconductor layer from the transparent layer 24 side. The n-type semiconductor layer is, for example, an n-type nitride semiconductor (e.g., n-type GaN). The active layers is, for example, a nitride semiconductor (e.g., n-type GaN) having a quantum-well structure. The p-type semiconductor layer is, for example, a p-type nitride semiconductor (e.g., p-type GaN). The semiconductor layer 23 is, for example, a blue light emitting diode (LED) that emits blue light (having a wavelength of 440 nm to 460 nm, for example). The reflective layer 25 is provided on a surface of the transparent layer 24 opposite to the semiconductor layer 23. The reflective layer 25 includes a material having a high reflectance. Specifically, the reflective layer 25 is a silver vapor-deposited film, an aluminum vapor-deposited film, a multilayer reflective film, or the like. Examples of the multilayer reflective film include a distributed Bragg reflector (DBR).

As illustrated in FIG. 4, in the light-emitting element 21, light LB emitted from the active layer of the semiconductor layer 23 is reflected by the reflective layer 25, and then enters the sealing lens 22 through an end face 24T of the transparent layer 24. The light LB having entered the sealing lens 22 passes through the sealing lens 22 and is emitted to the surroundings. It is to be noted that the light LB undergoes an optical action when passing through the sealing lens 22.

The sealing lens 22 is an optical member including a transparent resin such as silicone or acrylic, for example. The sealing lens 22 entirely covers the light-emitting element 21 and is configured to seal the light-emitting element 21. The sealing lens 22 has a refractive index between a refractive index of the semiconductor layer 23 of the light-emitting element 21 and a refractive index of air. The sealing lens 22 protects the light-emitting element 21 and improves extraction efficiency of light emitted from the light-emitting element 21. An external shape of the sealing lens 22 is not particularly limited as long as having an optical action as a lens for extracting the light LB emitted from the light-emitting element 21. For example, the external shape of the sealing lens 22 is not limited to a shape including a spherical surface, and may be a shape including an aspherical surface. Further, a light distribution direction of the light LB emitted from the light-emitting element 21 may be controlled by the sealing lens 22.

Since the light source 2 has a direct-potting type configuration, it is easy to shape the sealing lens 22 into a dome shape having an aspect ratio of 0.2 or greater and 1 or less. In particular, a luminance uniform characteristic such as luminance unevenness becomes good when the sealing lens 22 is shaped into a dome shape having an aspect ratio within a range from 0.4 to 0.6. Here, the aspect ratio is a ratio h/r between a height h and a radius r of the dome lens shape. When the aspect ratio is 1, the sealing lens 22 has a hemispherical shape.

### (Wavelength Conversion Sheet 8)

The wavelength conversion sheet 8 is disposed so as to be opposed to the multiple light sources 2. FIG. 5 is an enlarged cross-sectional view illustrating a part of the wavelength conversion sheet 8 illustrated in FIG. 3 in an enlarged manner. As illustrated in FIG. 5, the wavelength conversion sheet 8 includes, for example, particulate wavelength conversion substances 81. The wavelength conversion substance 81 includes, for example, a phosphor (a fluorescent material) such as a fluorescent pigment or a fluorescent dye, or a quantum dot. The wavelength conversion substance 81 is excited by light from the light source 2, converts the light from the light source 2 into light having a different wavelength than an original wavelength according to a principle of fluorescence emission, for example, and emits the light. It is to be noted that, in FIG. 5, the wavelength conversion substance 81 is illustrated in a particulate form for the sake of simplicity; however, in the present disclosure, the wavelength conversion substance 81 is not limited to a substance formed in a particulate form.

The wavelength conversion substance 81 included in the wavelength conversion sheet 8 absorbs blue light emitted from the light source 2, and converts a part of the blue light into red light (having a wavelength of 620 nm to 750 nm, for example) or green light (having a wavelength of 495 nm to 570 nm, for example). In this case, the light from the light source 2 passes through the wavelength conversion sheet 8, whereby red light, green light, and blue light are combined to generate white light. Alternatively, the wavelength conversion substance 81 included in the wavelength conversion sheet 8 may absorb blue light and convert a part of the blue light into yellow light. In this case, the light from the light source 2 passes through the wavelength conversion sheet 8, whereby yellow light and blue light are combined to generate white light.

It is preferable that the wavelength conversion substance 81 included in the wavelength conversion sheet 8 include a quantum dot. The quantum dot is a grain with a major diameter of 1 nm to 100 nm, and has a discrete energy level. Since the energy state of the quantum dot depends on its size, it is possible to freely select an emission wavelength by changing the size. Further, light emitted from the quantum dot has a narrow spectral width. By combining light having such a steep peak, a color gamut is enlarged. Therefore, using the quantum dot as the wavelength conversion substance makes it possible to easily enlarge the color gamut. Further, the quantum dot has high responsiveness, which makes it possible to efficiently use the light of the light source 2. In addition, the quantum dot also has high stability. The quantum dot is, for example, a compound of a Group 12 element and a Group 16 element, a compound of a Group 13 element and a Group 16 element, or a compound of a Group 14 element and a Group 16 element. Examples of the quantum dots include CdSe, CdTe, ZnS, CdS, PbS, PbSe, and CdHgTe. In addition, there is also a demand for a Cd-free quantum dot due to environmental regulations such as RoHS regulations. Examples of a core material include: InP-based material; a CsPbBr3-based material such as perovskite; Zn (Te, Se); and indium-silver sulfide which is one of ternary systems of a I-III-VI group.

### (Diffusion Sheet 7)

The diffusion sheet 7 is an optical member disposed between the wavelength conversion sheet 8 and the multiple light sources 2. The diffusion sheet 7 uniformizes an angular distribution of incident light. The diffusion sheet 7 may be one diffusion plate or one diffusion sheet, or may be two or more diffusion plates or two or more diffusion sheets. Further, the diffusion sheet 7 may be a plate-shaped optical member having a constant thickness and a constant hardness.

### (Spacer 6)

The spacer 6 is a member that maintains an optical distance between the light source 2 and the diffusion sheet 7.

### (Optical Sheet Group 9)

The optical sheet group 9 is an optical member disposed on a light-emitting surface side, i.e., a side opposite to the diffusion sheet 7, of the wavelength conversion sheet 8 when viewed from the wavelength conversion sheet 8. The optical sheet group 9 includes, for example, a sheet or a film that improves brightness. In the example illustrated in FIG. 1, the optical sheet group 9 is formed by stacking an optical sheet 91 and an optical sheet 92 in order on the wavelength conversion sheet 8. The optical sheet 91 and the optical sheet 92 may be joined to each other and integrated. The optical sheet 91 is, for example, a prism sheet. The optical sheet 92 is, for example, a reflective polarizing film such as a dual brightness enhancement film (DBEF). The number of optical sheets constituting the optical sheet group 9, the type and the stack order of the multiple optical sheets constituting the optical sheet group 9, and the like may be selected as desired.

### (Flexible Film 30)

The flexible film 30 is selectively provided on the resin layer 5. More specifically, the flexible film 30 is provided in an area of the front surface 1FS other than the area where the multiple light sources 2 are provided. The flexible film 30 is provided with openings 30K in areas overlapping with the multiple light sources 2 in the Z-axis direction. The opening 30K is a punched hole in which the light source 2 is arranged. In the area where the opening 30K is formed, the resin layer 5 is exposed, and the exposed resin layer 5 is covered with the sealing lens 22 of the light source 2. The flexible film 30 is joined to a front surface of the resin layer 5 extending on the XY plane. Specifically, the flexible film 30 is fixed with an adhesive or the like. The flexible film 30 is, for example, a reflective sheet, and has a high-reflectance with respect to the light LB from the light source 2 and the light LY with the wavelength converted by the wavelength conversion sheet 8. The flexible film 30 may include titanium oxide or silver (Ag) as a highly reflective material. Specifically, the flexible film 30 is, for example, a white resist layer. Examples of the white resist include inorganic materials such as titanium oxide (TiO₂) fine particles and barium sulfate (BaSO₄) fine particles, and organic materials such as porous acrylic resin fine particles having numerous pores for light-scattering and polycarbonate resin fine particles. As a constituent material of the flexible film 30, an epoxy-based resin may be also used. Further, the flexible film 30 may include a resin that contains fine particles of an inorganic material such as titanium oxide (TiO₂) fine particles and barium sulfate (BaSO₄) fine particles.

As described above, the flexible film 30 is a reflective sheet. Accordingly, returning light reflected by the wavelength conversion sheet 8 or the optical sheet group 9 among the light LB and the light LY is reflected by the flexible film 30 and is used as recycled light to generate white light. Therefore, it is possible to improve the entire brightness of the light-emitting device 100.

### (Relay Board 20)

The relay board 20 is a member that electrically and mechanically couples the multiple light source units 10 and relays the multiple light source units 10 with a power supply circuit, a drive circuit, and the like. The relay board 20 may be, for example, a film member having flexibility, like the light source board 1. The same material as that of the light source board 1 may be used as a constituent material of the relay board 20. That is, as the relay board 20, a resin-made film may be used including, for example, polyimide (PI), polyethylene terephthalate (PET), polycarbonate (PC), polyethylene naphthalate (PEN), polyetherimide (PEI), liquid crystal polymer (LCP), or fluororesin. Alternatively, an insulating resin-layer including, for example, polyimide or an epoxy-based resin and formed on a surface of a metal-base substrate including, for example, aluminum (Al) may be used as the relay board 20. Still alternatively, a film-base material including a glass-containing resin such as a glass epoxy resin typified by FR4 or a glass composite resin typified by CEM3 may be used as the relay board 20. Multiple wires 52 are formed on a front surface, i.e., a surface opposed to the light source board 1, of the relay board 20. Further, multiple wires 53 are formed on a rear surface, i.e., a surface opposed to the light source board 1, of the relay board 20. The wire 52 and the wire 53 are electrically coupled to each other via, for example, a via 20V.

The relay board 20 is joined to each of the multiple light source units 10 via the electrically conductive material layer 54. Specifically, the wire 51 and the wire 52 opposed to each other are joined to each other so as to sandwich the electrically conductive material layer 54 therebetween, for example. It is to be noted that each of the multiple light source units 10 is preferably joined to the relay board 20 at multiple positions with the electrically conductive material layers 54. Since each of the light source units 10 and the relay board 20 are coupled to each other at the multiple positions, each of the light source units is held more stably with respect to the relay board 20. In addition, since multiple channels such as a signal transmission path and a power supply path between each light source unit 10 and the relay board 20 are able to be secured, more functions are obtainable. As a constituent material of the electrically conductive material layer 54, an electrically conductive paste and a solder, or an anisotropic conductive adhesive (ACA) is preferably used, for example.

### 1.2 Workings

In the light-emitting device 100 of the present embodiment, as illustrated in FIG. 3, a part of the blue light LB emitted from the light source 2 is converted into the light LY with a wavelength converted by (emitted from) the wavelength conversion substance included in the wavelength conversion sheet 8. The light LY with the converted wavelength is, for example, red light, green light, or yellow light. The light LY with the converted wavelength is uniformly reflected and emitted from the wavelength conversion sheet 8 in all directions on average. The blue light LB not absorbed by the wavelength conversion substance 81 among the blue light LB emitted from the light source 2 is also uniformly emitted from the wavelength conversion sheet 8 in all directions on average. The blue light LB not absorbed by the wavelength converting material 81 (FIG. 5) among the blue light LB emitted from the light source 2 is emitted as it is from the wavelength conversion sheet 8. Light directed forward among the blue light LB with a wavelength not converted and light directed forward among the light LY with a converted wavelength are combined to generate white light, which is emitted forward (outside the light source device).

In the light-emitting device 100 of the present embodiment, the multiple light source units each including the multiple light sources arranged thereon are coupled to one relay board 20. It is therefore possible to finely adjust the arrangement positions for the multiple light source units 10, facilitating optimization of the arrangement position of each light source 2. This is also advantageous for reducing the weight of the light-emitting device 100. That is, by coupling the multiple light source units 10 to one relay board 20, it is possible to reduce the amount of a material used for the light source board 1 and to reduce the weight and cost of the light-emitting device 100 including the multiple light sources 2, as compared with a configuration in which the multiple light sources are arranged on one board-shaped substrate, for example. Therefore, according to the light-emitting device 100, it is possible to achieve a high-definition light-emission luminance distribution while achieving weight reduction and cost reduction.

In the light-emitting device 100 of the present embodiment, the multiple light source units 10 are provided so as to be aligned spaced apart from each other along the Y-axis. It is therefore possible to reduce the amount of the material used for the light source board 1 and to reduce the weight and cost of the light-emitting device 100 including the multiple light sources 2, as compared with the configuration in which the multiple light sources 2 are arranged on one board-shaped light source board.

Further, in the light-emitting device 100 of the present embodiment, the width W1 of the light source unit 10 in the Y-axis direction is narrower than the interval W2 between two of the multiple light source units 10 adjacent to each other in the Y-axis direction. Therefore, when a predetermined number of the light sources 2 are arranged as a whole of the light-emitting device 100, it is possible to reduce the amount of the material used for the light source board 1 and to further reduce the weight and cost of the light-emitting device 100, as compared with the case where the width W1 is equal to or larger than the interval W2, for example.

Further, in the light-emitting device 100 of the present embodiment, the multiple light sources 2 are aligned in one row along the X-axis direction on the light source board 1. Therefore, when a predetermined number of the light sources 2 are arranged in the light-emitting device 100 as a whole, it is possible to reduce the amount of the material used for the light source board 1 and to further reduce the weight and cost, as compared with a case where the multiple light sources 2 are aligned in multiple rows, for example.

Further, in the light-emitting device 100, the multiple light source units 10 and the relay board 20 are joined to each other via the electrically conductive material layer 54. It is therefore possible to simplify the coupling portions between the multiple light source units 10 and the relay board 20, and to reduce the size, thickness, and weight of the coupling portions, as compared with a case of joining with connectors, for example. Therefore, it is possible to reduce the size of each light source unit 10, and to increase the number of the light sources 2 per unit area, as compared with the case of using connectors. That is, it is possible to achieve high integration of the multiple light sources 2. In addition, the ease of manufacture is also improved as compared with the case of using connectors. In particular, in the light-emitting device 100, each of the multiple light source units 10 and the relay board 20 are joined to each other at multiple positions with the electrically conductive material layer 54. Since each of the multiple light source units 10 and the relay board 20 are coupled at the multiple positions, the multiple light source units 10 are held more stably with respect to the relay board 20. In addition, since multiple channels such as a signal transmission path and a power supply path between each light source unit 10 and the relay board 20 are able to be secured, more functions of the light-emitting device 100 are obtainable.

In addition, in the light-emitting device 100, the light source board 1 has flexibility, or both of the light source board 1 and the relay board 20 have flexibility. Accordingly, the light-emitting device 100 is suitably applied to a display device having a curved screen, for example.

Further, in the light-emitting device 100, the multiple light source units 10 are fixed and integrated by one flexible film 30. This makes it easy to handle a semi-finished product in the course of the manufacturing process, for example. For instance, it is possible to perform a batch operation of joining the multiple light source units 10 to the relay board 20, which enhances ease of manufacturing.

In addition, in the light-emitting device 100, the flexible film 30 is joined to the surface of the resin layer 5 of the light source unit 10, which is the surface extending on the XY plane. Therefore, the multiple light source units 10 are held more stably with respect to the flexible film 30.

Further, in the light-emitting device 100, the flexible film 30 has the openings 30K in the areas overlapping with the light sources 2 in the Z-axis direction. Therefore, even when the flexible film 30 is disposed on the light-emitting side of the light source 2, it is possible to join the flexible film 30 to the multiple light source units 10 while avoiding the areas where the light sources 2 are present. Therefore, it is possible to avoid inhibiting the progress of emitted light by the flexible film 30.

Further, in the light-emitting device 100, the driving elements that drive the multiple light sources 2 are provided on at least one of the relay board 20 or the light source board 1. It is therefore possible to drive the multiple light sources 2 at a higher speed than when the driving elements 40 are provided outside the light-emitting device 100. In particular, since the driving elements 40 are provided on the light source board 1 and drive some of the light sources 2 in the vicinity of the driving elements 40 among the multiple light sources 2 provided on the light source board 1, it is possible to further enhance responsiveness of the light sources 2.

### 1.3 Effect

As described above, according to the light-emitting device 100 of the present embodiment, it is possible to arrange the multiple light sources at a higher density and to achieve excellent light emission performance. In addition, it is also possible to achieve weight reduction.

### 1.4 Modification Examples of First Embodiment

### First Modification Example

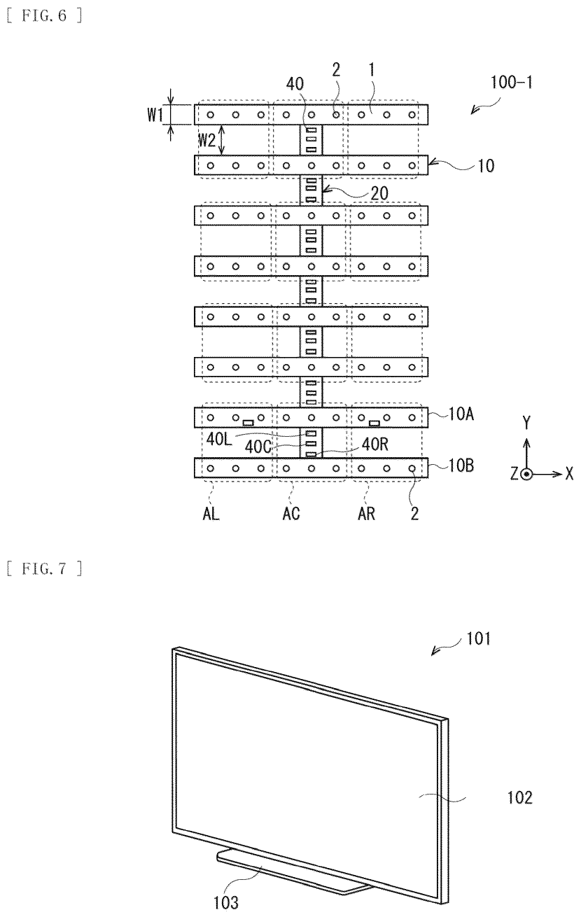

FIG. 6 is a plan view illustrating a configuration example of a light-emitting device 100-1 according to a first modification example of the first embodiment. In the light-emitting device 100-1 according to the first modification example, all of the driving elements 40 are provided on the relay board 20. In the light-emitting device 100-1, the multiple light sources 2 provided in both of two light source units 10 adjacent to each other in the Y-axis direction are driven by the driving element 40 provided between the two light source units 10. Specifically, as illustrated in FIG. 6, for example, the unit areas AL, AC, and AR are set so as to extend over both a light source unit 10A and a light source unit 10B. Here, the multiple light sources 2 provided in the unit area AL are coupled to the driving element 40L by the wire 4, and are driven and controlled by the driving element 40L, for example. Further, the light sources 2 provided in the unit area AC are coupled to the driving element 40C by the wire 4, and are driven and controlled by the driving element 40C. Further, the light sources 2 provided in the unit area AR are coupled to the driving element 40R by the wire 4, and are driven and controlled by the driving element 40R. As described above, in the present disclosure, it is possible to set the unit in which the drive control of the multiple light sources 2 is performed as desired.

In the example illustrated in FIG. 6, the six light sources 2 are arranged in each of the unit areas AL, AC, and AR; however, the present disclosure is not limited thereto. The number of the light sources 2 included in each of the unit areas AL, AC, and AR may be one or two, or may be four or more.

### 2. Second Embodiment

### 2.1 Configuration

FIG. 7 illustrates an external appearance of a display apparatus 101 according to a second embodiment of the present technology. The display apparatus 101 includes the light-emitting device 100, and is used as a flat-screen television apparatus, for example. The display apparatus 101 has a configuration in which a flat plate-shaped body 102 for image display is supported by a stand 103. It is to be noted that the display apparatus 101 is used as a stationary display apparatus that is placed on a horizontal surface of a floor, a shelf, a table or the like in a state where the stand 103 is attached to the body 102. Alternatively, the display apparatus 101 may be used as a wall-mounted display apparatus in a state where the stand 103 is detached from the body 102.

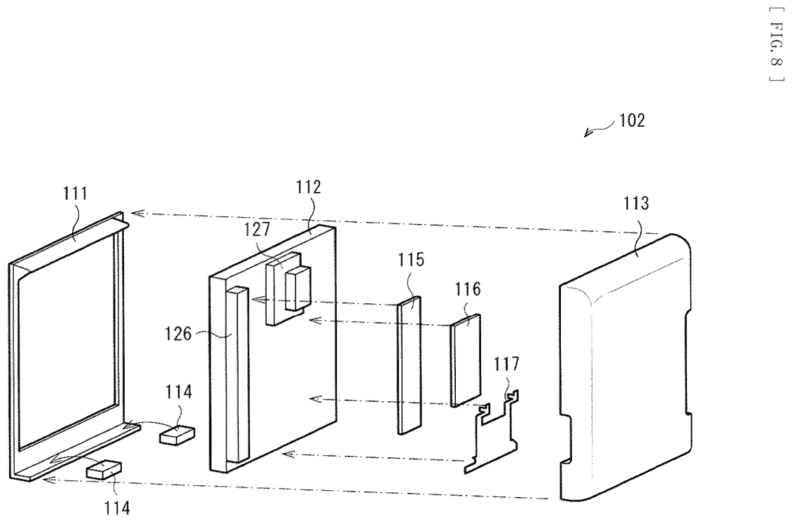

FIG. 8 is an exploded view of the body 102 illustrated in FIG. 7. The body 102 includes, for example, a front exterior member (a bezel) 111, a panel module 112, and a rear exterior member (a rear cover) 113 in this order from a front side (a viewer side). The front exterior member 111 is a frame-like member that covers a peripheral edge of a front surface of the panel module 112, and a pair of speakers 114 are disposed on a lower portion of the frame-like member. The panel module 112 is fixed to the front exterior member 111. A power supply board 115 and a signal board 116 are mounted on a rear surface of the panel module 112, and a fixing bracket 117 is fixed to the rear surface of the panel module 12. The fixing bracket 117 is for fixing a wall mounting bracket, fixing the boards or the like, and fixing the stand 103. The rear exterior member 113 covers the rear surface and a side surface of the panel module 112.

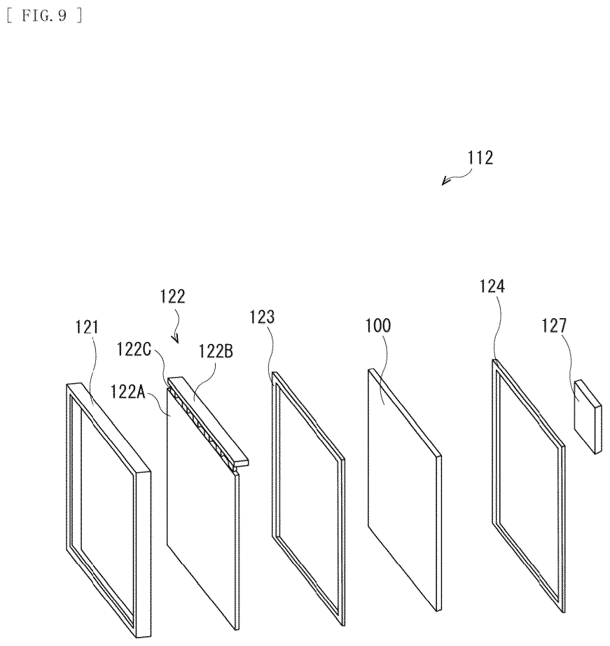

FIG. 9 is an exploded view of the panel module 112 illustrated in FIG. 8. The panel module 112 includes, for example, a front housing (a top chassis) 121, a liquid crystal panel 122, a frame-like member (a middle chassis) 123, the light-emitting device 100, a rear housing (a back chassis) 124, and a timing controller board 127 in this order from the front side (the viewer side).

The front housing 121 is a frame-like metal component that covers a peripheral edge of a front surface of the liquid crystal panel 122. The liquid crystal panel 122 includes, for example, a liquid crystal cell 122A, a source board 122B, and a flexible board 122C such as a chip-on-film (COF) that couples these components. The frame-like member 123 is a frame-like resin component that holds the liquid crystal panel 122. The rear housing 124 is a metal component including iron (Fe) or the like and housing the liquid crystal panel 122, the frame-like member 123, and the light-emitting device 100. The timing controller board 127 is also mounted on a rear surface of the rear housing 124.

FIG. 10 is a schematic plan view illustrating a more specific configuration example of the panel module 112. In the example of the light-emitting device 100 illustrated in FIG. 10, twelve light source units 10 in total are arranged in an area corresponding to a display area of the liquid crystal panel 122 extending in an H direction (a horizontal direction) and a V direction (a vertical direction). Specifically, six rows of the light source units 10 are aligned in the H direction, and two rows of the light source units 10 are aligned in the V direction. In each of the light source units 10, for example, longitudinal directions of the multiple light source boards 1 correspond to the H direction, and a longitudinal direction of the relay board 20 corresponds to the V direction. It is to be noted that illustration of the flexible film 30 is omitted in FIG. 10. As illustrated in FIG. 10, in the panel module 112, the timing controller board 127 is provided in a central area of the light-emitting device 100, for example. The timing controller board 127 and the multiple light source units 10 (10-1 to 10-12) are respectively coupled to each other with, for example, cables CB (CB1 to CB12) and connectors CN (CN1 to CN12).

### 2.2 Workings and Effects

In the display apparatus 101, the liquid crystal panel 122 selectively passes light from the light-emitting device 100 to display images. Here, as described in the first embodiment, an improvement in display quality of the display apparatus 101 is expected since the display apparatus 101 includes the light-emitting device 100 having excellent light-emission controllability and enhanced light-emission efficiency.

### 2.3 Modification Example of Second Embodiment

### First Modification Example

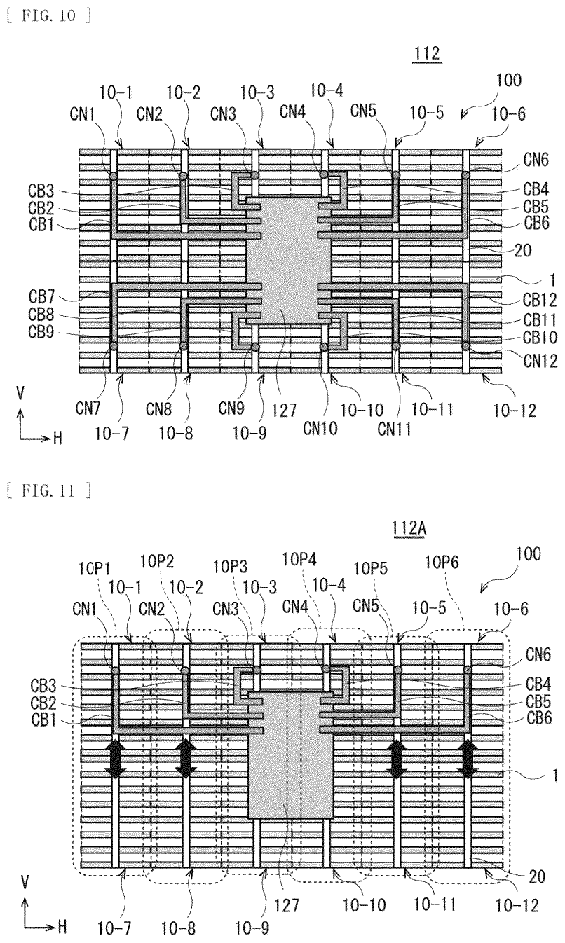

FIG. 11 is a schematic plan view of a panel module 112A according to a first modification example of the second embodiment. In the panel module 112 illustrated in FIG. 10, the timing controller board 127 and all the light source units 10 are individually and directly coupled with the cables CB and the connectors CN. In contrast, in the panel module 112A, the relay boards 20 of two light source units 10 adjacent to each other in the V-direction are electrically coupled to each other to form six light source unit pairs 10P, for example. Specifically, the light source units 10-1 to 10-6 are respectively coupled to the light source units 10-7 to 10-12 to form light source unit pairs 10P1 to 10P6. The relay boards 20 may be coupled to each other with, for example, a board-to-board connector or a flexible printed circuit board (FPC) and an anisotropic conductive adhesive (ACA). The timing controller board 127 and the six light source unit pairs 10P1 to 10P6 are coupled to each other with the cables CB1 to CB6 and the connectors CN1 to CN6, respectively.

According to the panel module 112A of FIG. 11, it is possible to reduce the number of the cables CB and the connectors CN as compared with the panel module 112 (FIG. 10) of the second embodiment described above when the same number of the light source units 10 are used.

### Second Modification Example

FIG. 12 is a schematic plan view of a light-emitting device 100B constituting a panel module 112B according to a second modification example of the second embodiment. In the light-emitting device 100B of the panel module 112B according to the present modification example, four rows of the light source units 10 are aligned in the H direction, and two rows of the light source units 10 are aligned in the V direction. Further, in each of the light source units 10-1 to 10-8, the longitudinal directions of the multiple light source boards 1 correspond to the V direction, and the longitudinal direction of the relay board 20 corresponds to the H direction. In the panel module 112B, the relay boards 20 of two light source units 10 adjacent to each other in the H-direction may be electrically coupled to form four light source unit pairs 10P1 to 10P4 in total, for example. Specifically, a light source unit pair 10P1 in which the relay boards 20 of the light source units 10-1 and 10-2 are coupled, a light source unit pair 10P2 in which the relay boards 20 of the light source units 10-3 and 10-4 are coupled, a light source unit pair 10P3 in which the relay boards 20 of the light source units 10-5 and 10-6 are coupled, and a light source unit pair 10P4 in which the relay boards 20 of the light source units 10-7 and 10-8 are coupled may be formed. The relay boards 20 are coupled to each other as described above. In the light-emitting device 100B, the timing controller board 127 and the light source unit pairs 10P1 to 10P4 are coupled with the connectors CN1 to CN4. It is to be noted that, in the light-emitting device 100B, for example, the relay boards 20 of the four light source units 10-1 to 10-4 aligned in the H-direction may be electrically coupled, and the relay boards 20 of the four light source units 10-5 to 10-8 may be electrically coupled. Further, in the light-emitting device 100B, the timing controller board 127 and all the light source units 10 may be individually and directly coupled to each other with the cables CB and the connectors CN.

### Third Modification Example

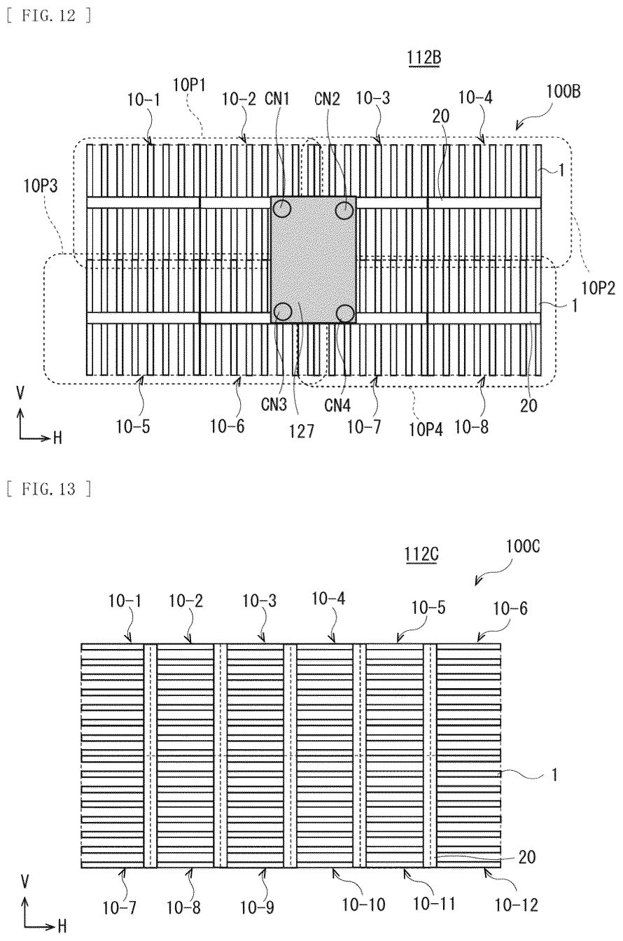

FIG. 13 is a schematic plan view of a light-emitting device 100C constituting a panel module 112C according to a third modification example of the second embodiment. In the light-emitting device 100C of the panel module 112C of the present modification example, six rows of the light source units 10 are aligned in the H direction, two rows of the light source units 10 are aligned in the V direction, as in the light-emitting device 100 of the panel module 112 of FIG. 10. In each of the light source units 10, the longitudinal directions of the multiple light source boards 1 correspond to the H direction, and the longitudinal direction of the relay board 20 corresponds to the V direction. However, the relay board 20 is provided so as to extend over two light source units 10 adjacent to each other in the H direction at a boundary portion between the two light source units 10. The relay board 20 provided at the boundary portion between the two adjacent light source units 10 is shared by the two light source units 10.

According to the panel module 11C of FIG. 13, it is possible to reduce the number of the relay boards 20 as compared with the panel module 112 (FIG. 10) according to the second embodiment when the same number of the light source units 10 are used.

### 3. Other Modification Examples

Although the present disclosure has been described above with reference to the embodiments and the modification examples, the present disclosure is not limited to the above-described embodiments and the like, and various modification examples may be made. For example, materials, types, arrangement positions, shapes, and the like of the constituent elements of the light-emitting device described in the above embodiments are not limited to those described above.

### 3.1 Modification Example 3-1

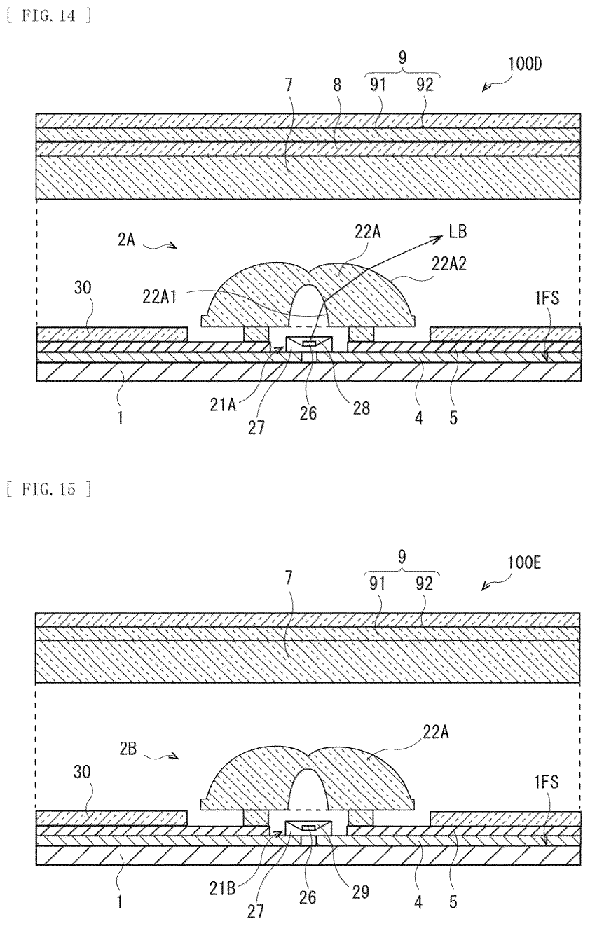

FIG. 14 is an enlarged cross-sectional view illustrating a part of a light-emitting device 100D according to a modification example 3-1 of the present disclosure. In the first embodiment, the light-emitting element 21 is sealed with the sealing lens 22; however, the present disclosure is not limited thereto. The light-emitting device 100A includes a light source 2A instead of the light source 2. The light source 2A has a light-emitting element 21A instead of the light-emitting element 21, and has a cap lens 22A instead of the sealing lens 22.

The light-emitting element 21A is, for example, a packaged blue LED. Specifically, the light-emitting element 21A includes a light-emitting layer 26, a base 27, and a sealing material 28. The base 27 has a concave holding portion. The light-emitting layer 26 is disposed on a bottom surface of the holding portion of the base 27. The holding portion of the base 27 is filled with the sealing material 28. The light-emitting layer 26 is, for example, a point light source, and is specifically a blue LED. The base 27 is mounted on the light source board 1 by soldering or the like via an external electrode including a lead frame or the like. The holding portion of the base 27 preferably has a surface having a high reflectance with respect to light from the light-emitting layer 26. The surface of the holding portion of the base 27 may include, for example, Ag as a material having a high reflectance. The sealing material 28 includes, for example, a transparent resin such as silicone or acrylic. The cap lens 22A is disposed directly above the light-emitting element 21A while being spaced apart from the light-emitting element 21A. At a center position of the cap lens 22A, a light incident surface 22A1 having a concave shape toward the light-emitting element 21A is provided so as to face the light-emitting element 21A in the Z-axis direction. In addition, the cap lens 22A has a light-emitting surface 22A2 having a convex shape toward the diffusion sheet 7, for example. The light incident surface 22A1 and the light-emitting surface 22A2 each exert a diffusing action on the blue light LB from the light-emitting element 21A.

In the light-emitting device 100A having such a configuration, the blue light emitted from the light-emitting element 21A is diffused by the cap lens 22A and the diffusion sheet 7, and then converted from the blue light to white light when passing through the wavelength conversion sheet 8. The white light obtained as a result of the conversion of the blue light is further subjected to brightness enhancement or is uniformized by the optical sheet group 9, and is incident onto the liquid crystal display panel or the like.

### 3.2 Modification Example 3-2

In the light-emitting device 100D according to the modification example 3-1 described above, the packaged blue LED is used as the light-emitting element 21A; however, the present disclosure is not limited thereto. For example, as with a light-emitting element 21B of a light-emitting device 100E according to a modification example 3-2 of the present disclosure illustrated in FIG. 15, a packaged white LED may be adopted instead of the packaged blue LED. The light-emitting element 21B includes: the light-emitting layer 26 including, for example, a blue LED; a base 27; and a sealing material encapsulant 29 including a transparent resin containing wavelength conversion substances. It is to be noted that, in the light-emitting device 100E, the wavelength conversion sheet 8 is unnecessary. This is advantageous to reduce the thickness of the entire configuration, as compared with the light-emitting device 100D of FIG. 14.

### 3.3 Modification Example 3-3

Further, the light-emitting device of the present disclosure is not limited to the one in which the lens is arranged on the light-emission side of the light-emitting element. For example, as with a light-emitting device 100F according to a modification example 3-3 of the present disclosure illustrated in FIG. 16, multiple light-emitting elements 21C that are packaged blue LEDs, for example, may be arranged without providing various lenses. Each of the light-emitting elements 21C has substantially the same configuration as the configuration of the light-emitting element 21A illustrated in FIG. 10, and includes the light-emitting layer 26 that is, for example, a blue LED, the base 27, and the sealing material 28. In the light-emitting device 100F having such a configuration, blue light emitted from the light-emitting element 21C is diffused by the diffusion sheet 7, and then converted from the blue light to white light when passing through the wavelength conversion sheet 8. The white light obtained as a result of the conversion of the blue light is further subjected to brightness enhancement or uniformized by the optical sheet group 9, and is incident onto the liquid crystal display panel or the like.

### 3.4 Modification Example 3-4

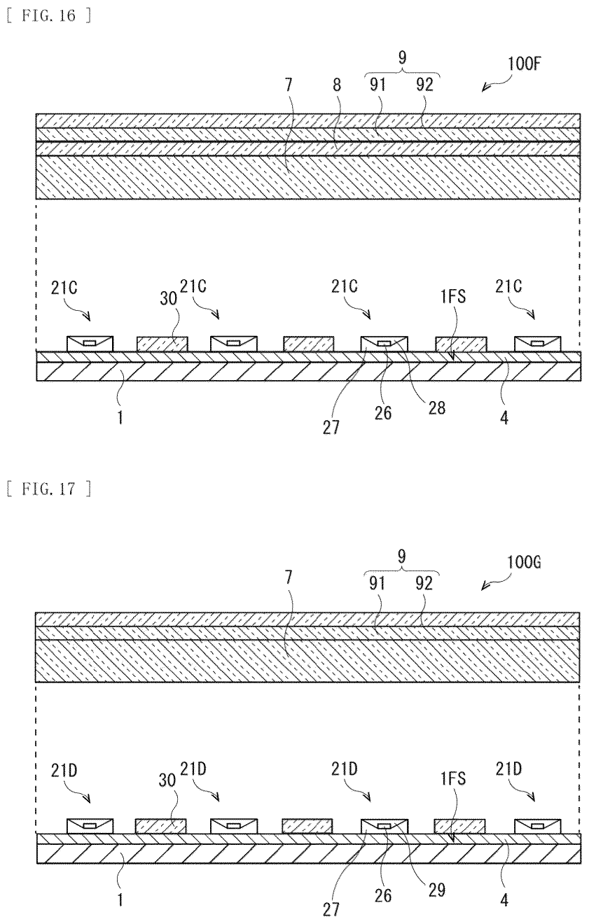

In the light-emitting device 100F according to the modification example 3-3 described above, the packaged blue LED is used as the light-emitting element 21C; however, the present disclosure is not limited thereto. For example, as with a light-emitting element 21D of a light-emitting device 100G according to a modification example 3-4 of the present disclosure illustrated in FIG. 17, a packaged white LED may be adopted instead of the packaged blue LED. The light-emitting element 21D has substantially the same configuration as the configuration of the light-emitting element 21B illustrated in FIG. 11, and includes, for example: the light-emitting layer 26 that is, for example, a blue LED; the base 27; and the sealing material 29 including a transparent resin containing wavelength conversion substances. In the light-emitting device 100G, the wavelength conversion sheet 8 is unnecessary. This is advantageous to reduce the thickness of the entire configuration, as compared with the light-emitting device 100F of FIG. 16.

### 3.5 Modification Example 3-5

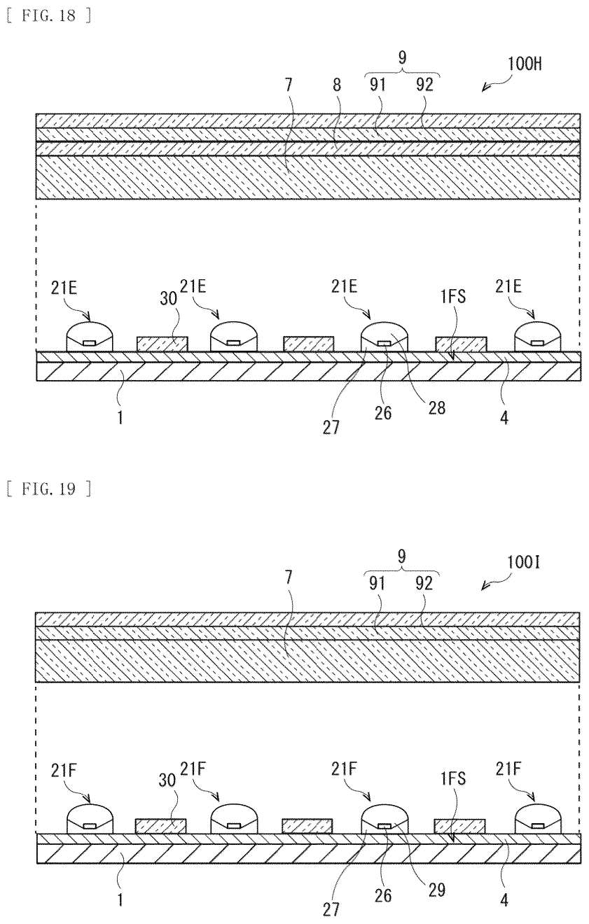

A light-emitting device 100H according to a modification example 3-5 of the present disclosure illustrated in FIG. 18 includes a light-emitting element 21E having a dome-shaped sealing material 28. The light-emitting element 21E has a configuration substantially the same as the configuration of the light-emitting element 21C except that the shape of the sealing material 28 differs. Since the sealing material 28 in the light-emitting element 21E has a dome-shape, the sealing material 28 is allowed to have a lensing effect. Therefore, a desired alignment performance is easily obtainable.

### 3.6 Modification Example 3-6

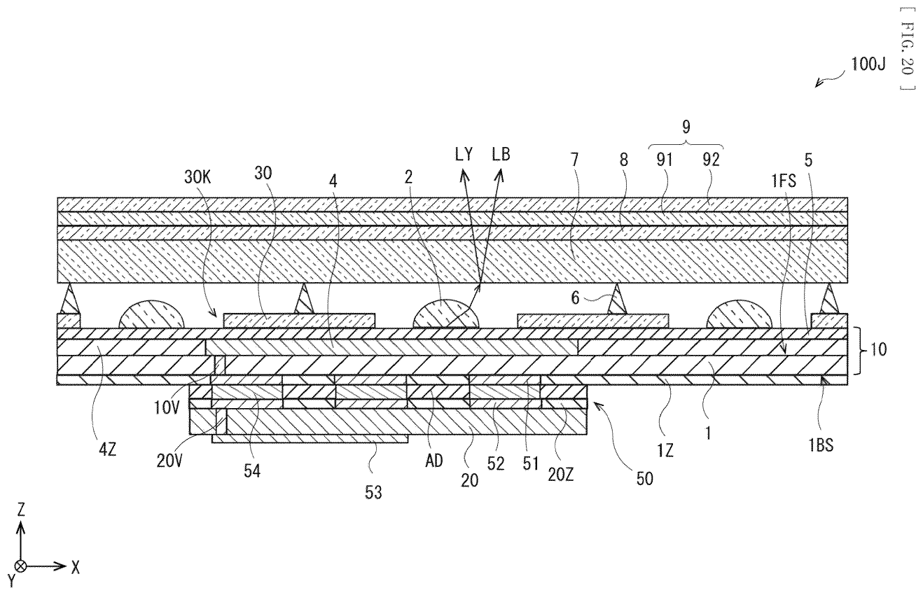

A light-emitting device 100I according to a modification example 3-6 of the present disclosure illustrated in FIG. 19 includes a light-emitting element 21F having a dome-shaped sealing material 29. The light-emitting element 21F has a configuration substantially the same as the configuration of the light-emitting element 21D except that the shape of the sealing material 28 differs. Specifically, the light-emitting element 21F includes: a light-emitting layer 26 that is, for example, a blue LED; the base 27; and the sealing material 29 including a transparent resin containing wavelength conversion substances. Since the sealing material 29 in the light-emitting element 21F has a dome-shape, the sealing material 29 is allowed to have a lensing effect. Therefore, a desired alignment performance is easily obtainable.

### 3.7 Modification Example 3-7

FIG. 20 illustrates a cross-sectional configuration of a light-emitting device 100J according to a modification example 3-7 of the present disclosure, and corresponds to FIG. 3 illustrating the light-emitting device 100 of the first embodiment. In the light-emitting device 100J, an insulating layer 1Z is formed on the back surface 1BS of the light source board 1, and an insulating layer 20Z is formed on the front surface of the relay board 20. Further, in the light-emitting device 100H, the back surface 1BS of the light source board 1 and the front surface of the relay board 20 are directly or indirectly joined to each other with an adhesive layer AD. In the light-emitting device 100H, an anisotropic conductive adhesive is preferably used as a constituent material of the electrically conductive material layers 54, for example. Further, the adhesive layer AD may be an anisotropic conductive adhesive like the electrically conductive material layer 54. In this case, the adhesive layer AD and the electrically conductive material layer 54 may be formed simultaneously using the same anisotropic conductive adhesive. The anisotropic conductive adhesive is obtained by dispersing multiple electrically conductive particles in an insulating adhesive. Therefore, when the anisotropic conductive adhesive is sandwiched and pressed between the wire 51 and the wire 52, multiple conductive particles are electrically coupled to each other and constitute the electrically conductive material layer 54. In contrast, the anisotropic conductive adhesive in an area other than the area sandwiched between the wire 51 and the wire 52 constitutes the adhesive layer AD exhibiting an insulating property. In the light-emitting device 100H, the insulating layer 1Z and the insulating layer 20Z may not be provided.

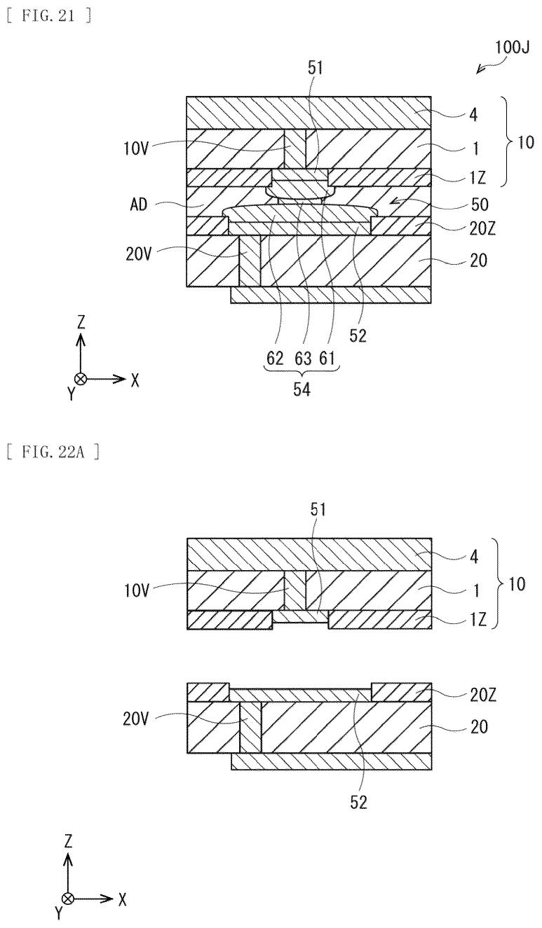

FIG. 21 is a cross-sectional view illustrating a detailed configuration of the electrically conductive material layer 54 of a light-emitting device 100J. As illustrated in FIG. 21, the electrically conductive material layer 54 includes a bump 61, a bump 62, and an electrically conductive material 63. The bump 61 is provided on the wire 51. The bump 62 is provided on the wire 52. The electrically conductive material 63 is sandwiched between the bump 61 and the bump 62. As constituent materials of the bumps 61 and and the electrically conductive material 63, an electrically conductive paste containing at least one of Ag, Cu, Ni, or Sn, a solder, and an anisotropic conductive adhesive are preferably used, for example.

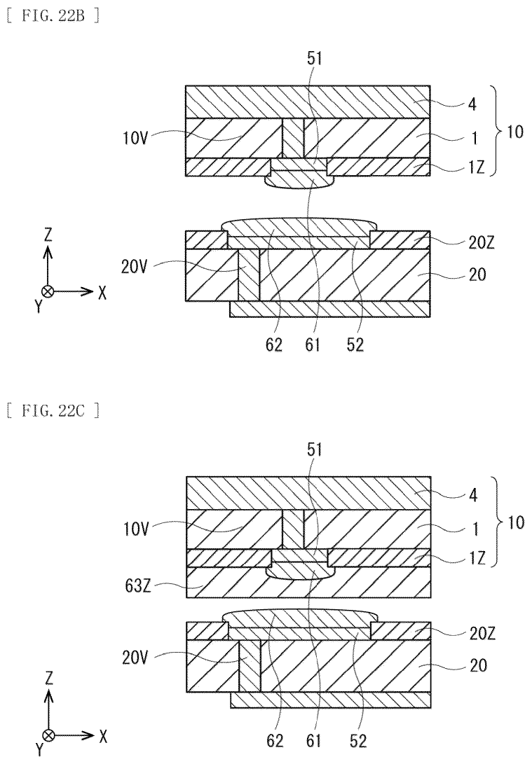

FIGS. 22A to 22C are cross-sectional views describing a process of forming the electrically conductive material layer 54 of the light-emitting device 100H. First, as illustrated in FIG. 22A, the wire 51 of the light source unit 10 and the wire 52 of the relay board 20 are disposed to oppose to each other. Next, as illustrated in FIG. 22B, the bump 61 is formed so as to cover the wire 51, and the bump 62 is formed so as to cover the wire 52. Subsequently, as illustrated in FIG. 22C, an anisotropic conductive adhesive 63Z is formed so as to cover the bumps 61. It is to be noted that the anisotropic conductive adhesive 63Z may be formed so as to cover the bumps 62. Lastly, the anisotropic conductive adhesive 63Z is pressed between the bump 61 and the bump 62 to form the electrically conductive material 63, and the light source unit 10 and the relay board 20 are joined to each other. As a result, the electrically conductive material layer 54 is formed, and the coupling portion 50 is completed.

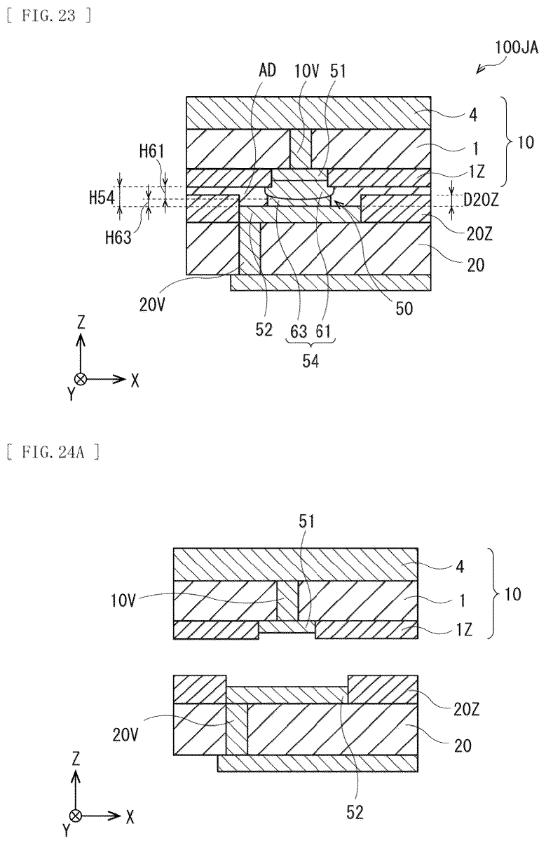

It is to be noted that, in FIG. 21, the bump 61 and the bump 62 are formed on both of the light source unit 10 and the relay board 20; however, in the present disclosure, as in a light-emitting device 100JA illustrated in FIG. 23, the bump may be provided only on either one of the light source unit 10 and the relay board 20. In the light-emitting device 100JA of FIG. 23, the bump 61 is provided only on the wire 51 of the light source unit 10, and the wire 52 of the relay board 20 is in direct contact with the electrically conductive material layers 54. Alternatively, the bump 62 may be provided only on the wire 52 of the relay board 20, and the wire 51 of the light source unit 10 may be directly in contact with the electrically conductive material layer 54. In FIG. 23, a depth D20Z is a difference between an upper surface of the insulating layer 20Z and an upper surface of the wire 52 in the Z-axis direction. The upper surface of the insulating layer 20Z refers to a surface of the insulating layer 20Z facing the insulating layer 1Z. The upper surface of the wire 52 refers to a surface of the wire 52 facing the bump 61. In addition, in FIG. 23, a height H61 is a difference between a position, closest to the upper surface of the wire 52 (distal end portion), of a lower surface of the bump 61 and a lower surface of the insulating layers 1Z in the Z-axis direction. The lower surface of the bump 61 refers to a surface of the bump 61 facing the wire 52. The lower surface of the insulating layer 1Z refers to a surface of the insulating layer 1Z facing the insulating layer 20Z. Further, a height H63 is a thickness of a part of the electrically conductive material 63 sandwiched between the distal end portion of the bump 61 and the upper surface of the wire 52. A sum of the height H61 and the height H63 is defined as a height H54. In the light-emitting device 100JA of FIG. 23, it is desirable that the height H54 be larger than the depth D20Z (H54>D20Z). A reason for this is that sufficient electric conductivity of the electrically conductive material 63 is obtainable.

As described above, in the light-emitting device 100JA in which the bump is provided only on either one of the light source unit 10 and the relay board 20, a distance between the light source board 1 of the light source unit 10 and the relay board 20 in the thickness direction (the Z-axis direction) is able to be reduced, as compared with the light-emitting device 100J in which the bumps are formed on both of the light source unit 10 and the relay board 20. Thus, the thickness of the light-emitting device 100JA is made thinner than the thickness of the light-emitting device 100J. In addition, in the light-emitting device 100JA, a step of forming the bump 62 may be omitted. This further simplifies the manufacturing process, as compared with the light-emitting device 100H.

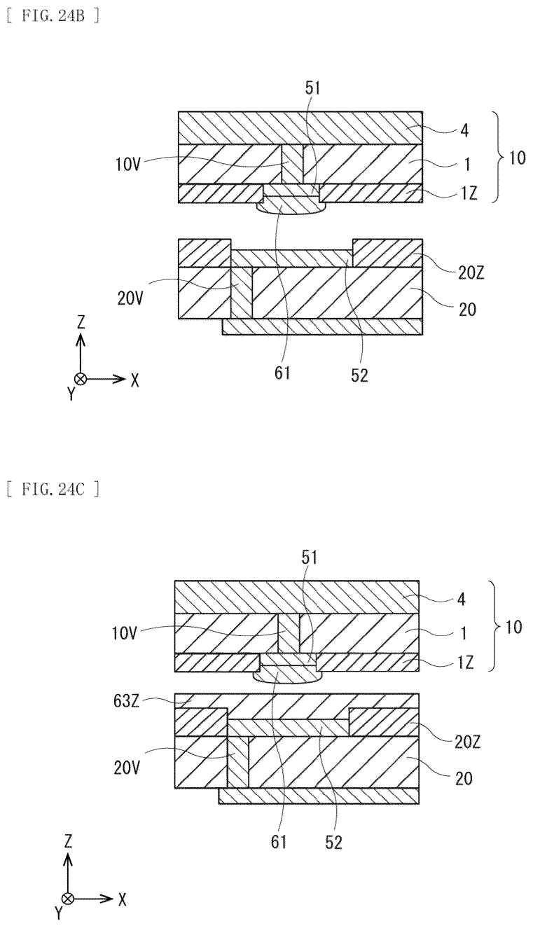

FIGS. 24A to 24C are cross-sectional views describing a process of forming the coupling portion 50 of the light-emitting device 100JA. First, as illustrated in FIG. 24A, the wire 51 of the light source unit 10 and the wire 52 of the relay board 20 are disposed to oppose to each other. Next, as illustrated in FIG. 24B, the bump 61 is formed so as to cover the wires 51. Subsequently, as illustrated in FIG. 24C, the anisotropic conductive adhesive 63Z is formed so as to cover the bump 61. Lastly, the anisotropic conductive adhesive 63Z is pressed between the bump 61 and the bump 62 so that the light source unit 10 and the relay board 20 are joined to each other. As a result, the electrically conductive material layer 54 is formed, and the coupling portion 50 is completed.

Here, as apparent from the comparison between the light-emitting device 100J illustrated in FIG. 21 and the light-emitting device 100JA illustrated in FIG. 23, when the dimension of the bump 61 in the X-axis direction is the same, the dimension in the X-axis direction of the electrically conductive material 63 in the light-emitting device 100JA is able to be made larger than that in the light-emitting device 100J. In the light-emitting device 100J illustrated in FIG. 21, both the surface of the bump 61 and the surface of the bump 62 are convex surfaces. Therefore, when the electrically conductive material 63 is formed, the electrically conductive particles contained in the anisotropic conductive adhesive 63Z pressed between the bump 61 and the bump 62 are likely to flow out from the area between the bump 61 and the bump 62. In contrast, in the light-emitting device 100JA illustrated in FIG. 23, although the front surface of the bump 61 is a convex surface, the upper surface of the wire 52 opposed to the bump 61 is a flat surface. Therefore, the electrically conductive particles contained in the anisotropic conductive adhesive 63Z pressed between the bump 61 and the upper surface of the wire 52 are relatively unlikely to flow out from the area between the bump 61 and the upper surface of the wire 52. The same applies to the Y-axis direction.

Although the wire 51 is provided in the light-emitting device 100JA of FIG. 23, the bump 64 may be formed instead of the bump 61 without providing the wire 51 and the insulating layers 1Z, as in the light-emitting device 100JB of FIG. 25. It is to be noted that the bump 64 is provided so as to fill the via hole 10VH extending through the light source board 1 and protrude from the back surface 1BS of the light source board 1 toward the relay board 20. Accordingly, the light-emitting device 100JB has a simpler and thinner configuration than the light-emitting device 100JA.

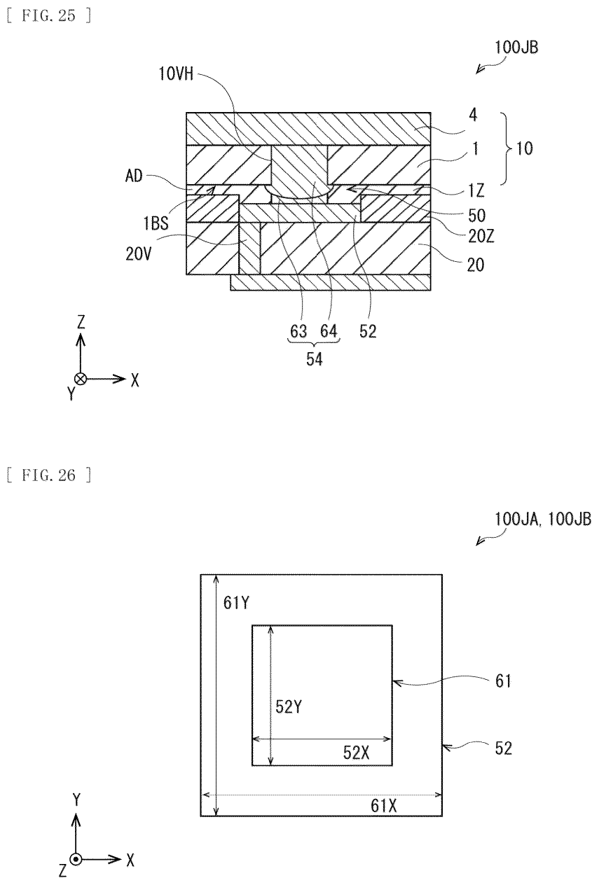

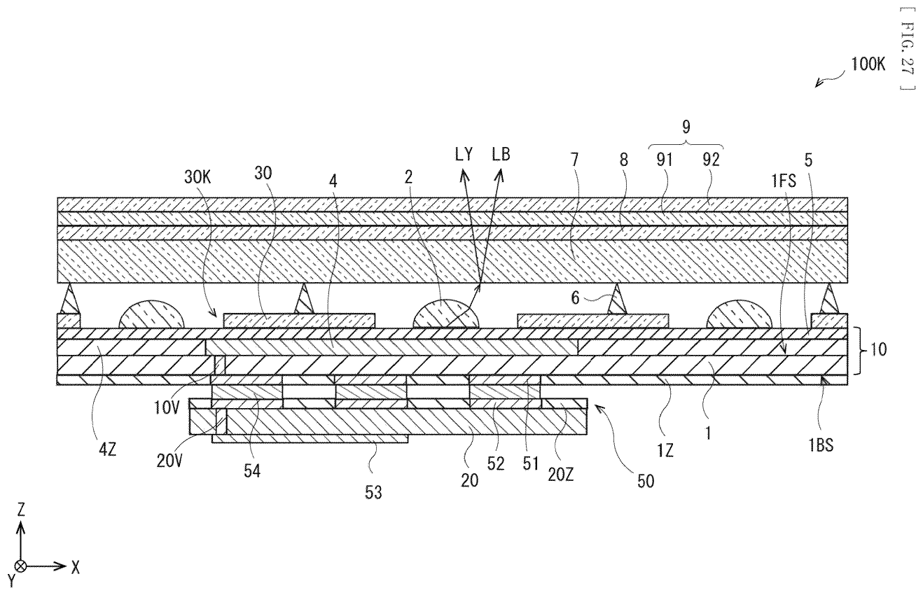

Further, as illustrated in FIG. 26, in both the light-emitting device 100JA and the light-emitting device 100JB, it is desirable that a dimension 61X in the X-axis direction of the bump 61 be smaller than a dimension 52X in the X-axis direction of an exposed part of the wire 52 opposed to the bump 61, and that a dimension 61Y in the Y-axis direction of the bump 61 be smaller than a dimension 52Y in the Y-axis direction of the exposed part of the wire 52 opposed to the bump 61. FIG. 26 is a schematic plan view schematically illustrating an exemplary positional relation between the bump 61 and the exposed part of the wire 52 on the XY plane. In the light-emitting device 100JA and the light-emitting device 100JB, for example, the dimension 52X is preferably 1.5 times or greater and 3 times or less of the dimension 61X, and the dimension 52Y is preferably 1.5 times or greater and 3 times or less of the dimension 61Y. By making the dimension of the bump 61 on the XY plane smaller than the dimension of the exposed part of the wire 52 on the XY plane as described above, it is possible to secure a margin for alignment between the light source unit 10 and the relay board 20 on the XY plane. It is to be noted that, in FIG. 26, the dimension 52X and the dimension 52Y are substantially equal to each other, and the dimension 61X and the dimension 61Y are substantially equal to each other; however, the present disclosure is not limited thereto. That is, a planar shape of the bump 61 and a planar shape of the exposed portion of the wire 52 are each not limited to a substantially square shape and may be a substantially rectangular shape. Alternatively, these planar shapes may be rectangular shapes with rounded corners or may be substantially circular shapes or substantially elliptical shapes.

It is to be noted that, in the light-emitting devices 100JA and100JB, the ratio of the dimension 52X to the dimension 61X and the ratio of the dimension 52Y to the dimension 61Y may be changed according to an arrangement density of the multiple coupling portions 50 (the number of the coupling portions 50 per unit area) and arrangement positions of the coupling portions 50 on the XY plane. For example, the ratio of the dimension 52X to the dimension 61X and the ratio of the dimension 52Y to the dimension 61Y may be increased in a region in which the arrangement density of the coupling portions 50 is relatively low as compared with a region in which the arrangement density of the coupling portions 50 is relatively high, among light-emitting regions along the XY plane of the light-emitting devices 100JA an 100JB. Alternatively, at the coupling portion 50 at a position close to a center position of the relay board 20 in the Y-axis direction, the ratio of the dimension 52X to the dimension 61X and the ratio of the dimension 61Y to the dimension 52Y may be relatively small, and at the coupling portions 50 at positions close to both ends of the relay board 20 in the Y-axis direction, the ratio of the dimension 52X to the dimension 61X and the ratio of the dimension 61Y to the dimension 52Y may be relatively large.

### 3.8 Modification Example 3-8

FIG. 27 illustrates a cross-sectional configuration of a light-emitting device 100K according to a modification example 3-8 of the present disclosure and corresponds to FIG. 3 illustrating the light-emitting device 100 of the first embodiment. In the light-emitting device 100K, the insulating layer 1Z is formed on the back surface 1BS of the light source board 1, and the insulating layer 20Z is also formed on the front surface of the relay board 20. In the light-emitting device 100K, an electrically conductive paste containing, for example, Ag or Cu and a solder are preferably used as constituent materials of the electrically conductive material layer 54.

### 3.9 Modification Example 3-9

Although the display apparatus 101 including the liquid crystal panel 122 has been described as an example in the second embodiment, the present disclosure is not limited thereto. That is, although the light-emitting device 100 is used as the backlight of the liquid crystal panel 122 in the display apparatus 101, the light-emitting device 100 may be used as a display panel.

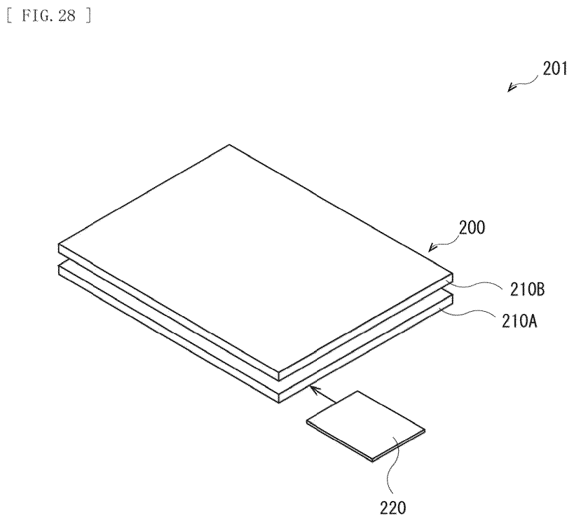

FIG. 28 schematically illustrates a display apparatus 201 including a display panel 200. The display apparatus 201 includes a display panel 210 and a control circuit 220 that controls driving of the display panel 210. The display apparatus 201 is a so-called LED display in which an LED is used as a display pixel. That is, the light source 2 of the light-emitting device 100 is used as a display pixel. The display panel 210 is formed by superimposing a mounting board 210A including the light-emitting device 100 and a counter board 210B on each other. The counter board 210B has a video display surface on a front surface (a surface opposite to the mounting board 210A), has a display region at a center portion thereof, and has a frame region serving as a non-display region around the display region. The counter board 210B is disposed, for example, at a position facing the mounting board 210A with a predetermined gap therebetween. It is to be noted that the counter board 210B may be in contact with an upper surface of the mounting board 210A. The counter board 210B includes, for example, a light-transmitting substrate that transmits visible light. Examples of the light-transmitting substrate include a glass substrate, a transparent resin substrate, and a transparent resin film.

Further, the effects described in the present specification are merely examples and are not limited to the description, and other effects may be obtained. For example, the light source is not limited to either one of a white light source and a blue light source, and may be a light source that emits another color, such as a red light source or a green light source. Further, in the above-described light-emitting device 100 and the like, the flexible film 30 is attached to the light-emitting surface side of each light source unit 10, and the multiple light source units 10 are fixed to the flexible film 30. However, the flexible film 30 may be attached to the back surface of each light source unit 10, which is opposite to the light-emitting surface. Further, the present technology may adopt the following configuration.

(1) A light-emitting device including:
multiple light source units each including
   a light source board extending in a first direction, and
   multiple light sources arranged along the first direction on the light source board; and
a relay member electrically coupled to each of the multiple light source units.

(2) The light-emitting device according to (1), in which the multiple light source units and the relay member are joined with an electrically conductive material interposed therebetween.

(3) The light-emitting device according to (1) or (2), in which the multiple light source units are aligned spaced apart from each other along a second direction perpendicular to the first direction.

(4) The light-emitting device according to (3), in which a width of each of the multiple light source units in the second direction is narrower than an interval of each two light source units adjacent to each other in the second direction among the multiple light source units.

(5) The light-emitting device according to (4), in which the multiple light sources are aligned in one row along the first direction on the light source board.

(6) The light-emitting device according to any one of (1) to (5), in which
the light source board has flexibility, or
both of the light source board and the relay member have flexibility.

(7) The light-emitting device according to any one of (1) to (6), further including
a sheet member to which the multiple light source units are fixed, the sheet member having flexibility.

(8) The light-emitting device according to (7), in which the sheet member is joined to a face of each of the multiple light source units, the face extending along the first direction.

(9) The light-emitting device according to (7) or (8), in which the sheet member has openings in respective areas overlapping with the multiple light sources in a third direction perpendicular to the first direction.

(10) The light-emitting device according to any one of (1) to (9), further including a driving element that drives the multiple light sources.

(11) The light-emitting device according to (10), in which the driving element is provided on the relay member, the light source board, or both.

(12) The light-emitting device according to (10), in which the driving element is provided on the light source board and configured to drive some of the multiple light sources provided on the light source board.

(13) The light-emitting device according to (10), in which
the driving element is provided on the relay member and configured to drive both of a first light source in a first light source unit of the multiple light source units and a second light source in a second light source unit of the multiple light source units.

(14) The light-emitting device according to any one of (1) to (13), in which each of the multiple light source units and the relay member are joined at multiple positions.

(15) The light-emitting device according to any one of (1) to (14), in which all of the multiple light sources are white light sources, or the multiple light sources include a red light source, a green light source, and a blue light source.

(16) The light-emitting device according to any one of (1) to (14), further including a wavelength conversion member, in which
the multiple light sources are blue light sources, and
the wavelength conversion member converts blue light received from the bule light sources into white light.

(17) The light-emitting device according to (16), in which the wavelength conversion member includes a quantum dot.

(18) A display apparatus including:
a light-emitting device; and
a display panel that displays an image using light from the light-emitting device, in which
the light-emitting device includes
   multiple light source units each including
      a light source board extending in a first direction, and
      multiple light sources arranged along the first direction on the light source board, and
   a relay member electrically coupled to each of the multiple light source units.

(19) A light-emitting device including:
multiple light source units each including
   a light source board extending in a first direction, and
   multiple light sources arranged along the first direction on the light source board; and
a sheet member to which the multiple light source units are fixed, the sheet member having flexibility.

(20) The light-emitting device according to any one of (1) to (18), further including multiple coupling portions electrically coupling the multiple light source units and the relay member, in which
the multiple light source units and the relay member overlap with each other at the multiple coupling portions in a thickness direction of the light source board, and
the multiple coupling portions each include
   a first bump formed on corresponding one of the light source units,
   a second bump formed on the relay member and opposed to the first bump in the thickness direction, and
   an electrically conductive material provided between the first bump and the second bump.

(21) The light-emitting device according to any one of (1) to (18), further including multiple coupling portions electrically coupling the multiple light source units and the relay member, in which
the multiple light source units and the relay member overlap with each other at the multiple coupling portions in a thickness direction of the light source board, and
the multiple coupling portions each include
   a bump formed on one of corresponding one of the light source units and the relay member,
   a pad formed on the other of the corresponding one of the light source units and the relay member and opposed to the bump in the thickness direction, and
   an electrically conductive material provided between the bump and the pad.

(22) The light-emitting apparatus according to (21), in which each of the multiple light source units further has an electrically conductive via coupled to the multiple light sources and extending through the light source board in the thickness direction.

(23) The light-emitting device according to (22), in which the bump is provided to cover the electrically conductive via.

(24) The light-emitting device according to (21), in which
a dimension of the bump in the first direction is smaller than a dimension of the pad in the first direction, and
a dimension of the bump in the second direction perpendicular to the first direction is smaller than a dimension of the pad in the second direction.

(25) The display apparatus according to (18), further including multiple coupling portions electrically coupling the multiple light source units and the relay member, in which
the multiple light source units and the relay member overlap with each other at the multiple coupling portions in a thickness direction of the light source board, and
   the multiple coupling portions each include
      a bump formed on one of corresponding one of the light source units and the relay member,
      a pad formed on the other of the corresponding one of the light source units and the relay member and opposed to the bump in the thickness direction, and
      an electrically conductive material provided between the bump and the pad.

The present application claims the benefits of Japanese Priority Patent Application No. 2022-032438 filed with the Japan Patent Office on Mar. 3, 2022 and Japanese Priority Patent Application No. 2022-075412 filed with the Japan Patent Office on Apr. 28, 2022, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. A light-emitting device comprising:
multiple light source units each including
a light source board extending in a first direction, and
multiple light sources arranged along the first direction on the light source board; and
a relay member electrically coupled to each of the multiple light source units.

2. The light-emitting device according to claim 1, wherein the multiple light source units and the relay member are joined with an electrically conductive material interposed therebetween.

3. The light-emitting device according to claim 1, wherein the multiple light source units are aligned spaced apart from each other along a second direction perpendicular to the first direction.

4. The light-emitting device according to claim 3, wherein a width of each of the multiple light source units in the second direction is narrower than an interval of each two light source units adjacent to each other in the second direction among the multiple light source units.

5. The light-emitting device according to claim 4, wherein the multiple light sources are aligned in one row along the first direction on the light source board.

6. The light-emitting device according to claim 1, wherein
the light source board has flexibility, or
both of the light source board and the relay member have flexibility.

7. The light-emitting device according to claim 1, further comprising
a sheet member to which the multiple light source units are fixed, the sheet member having flexibility.

8. The light-emitting device according to claim 7, wherein the sheet member is joined to a face of each of the multiple light source units, the face extending along the first direction.

9. The light-emitting device according to claim 7, wherein the sheet member has openings in respective areas overlapping with the multiple light sources in a third direction perpendicular to the first direction.

10. The light-emitting device according to claim 1, further comprising a driving element that drives the multiple light sources.

11. The light-emitting device according to claim 10, wherein the driving element is provided on the relay member, the light source board, or both.

12. The light-emitting device according to claim 10, wherein the driving element is provided on the light source board and configured to drive some of the multiple light sources provided on the light source board.

13. The light-emitting device according to claim 10, wherein the driving element is provided on the relay member and configured to drive both of a first light source in a first light source unit of the multiple light source units and a second light source in a second light source unit of the multiple light source units.

14. The light-emitting device according to claim 1, wherein each of the multiple light source units and the relay member are joined at multiple positions.

15. The light-emitting device according to claim 1, wherein
all of the multiple light sources are white light sources, or
the multiple light sources include a red light source, a green light source, and a blue light source.

16. The light-emitting device according to claim 1, further comprising a wavelength conversion member, wherein
the multiple light sources are blue light sources, and
the wavelength conversion member converts blue light received from the bule light sources into white light.

17. The light-emitting device according to claim 16, wherein the wavelength conversion member includes a quantum dot.

18. A display apparatus comprising:
a light-emitting device; and
a display panel having a display region that displays an image using light from the light-emitting device, wherein
the light-emitting device includes
multiple light source units each including
a light source board extending in a first direction, and
multiple light sources arranged along the first direction on the light source board, and
a relay member electrically coupled to each of the multiple light source units.

19. A light-emitting device comprising:
multiple light source units each including
a light source board extending in a first direction, and
multiple light sources arranged along the first direction on the light source board; and
a sheet member to which the multiple light source units are fixed, the sheet member having flexibility.

20. The light-emitting device according to claim 1, further comprising multiple coupling portions electrically coupling the multiple light source units and the relay member, wherein
the multiple light source units and the relay member overlap with each other at the multiple coupling portions in a thickness direction of the light source board, and
the multiple coupling portions each include
a first bump formed on corresponding one of the light source units,
a second bump formed on the relay member and opposed to the first bump in the thickness direction, and
an electrically conductive material provided between the first bump and the second bump.

21. The light-emitting device according to claim 1, further comprising multiple coupling portions electrically coupling the multiple light source units and the relay member, wherein
the multiple light source units and the relay member overlap with each other at the multiple coupling portions in a thickness direction of the light source board, and
the multiple coupling portions each include
a bump formed on one of corresponding one of the light source units and the relay member,
a pad formed on the other of the corresponding one of the light source units and the relay member and opposed to the bump in the thickness direction, and
an electrically conductive material provided between the bump and the pad.

22. The light-emitting apparatus according to claim 21, wherein each of the multiple light source units further has an electrically conductive via coupled to the multiple light sources and extending through the light source board in the thickness direction.

23. The light-emitting device according to claim 22, wherein the bump is provided to cover the electrically conductive via.

24. The light-emitting device according to claim 21, wherein
a dimension of the bump in the first direction is smaller than a dimension of the pad in the first direction, and
a dimension of the bump in the second direction perpendicular to the first direction is smaller than a dimension of the pad in the second direction.

25. The display apparatus according to claim 18, further comprising multiple coupling portions electrically coupling the multiple light source units and the relay member, wherein
the multiple light source units and the relay member overlap with each other at the multiple coupling portions in a thickness direction of the light source board, and
the multiple coupling portions each include
a bump formed on one of corresponding one of the light source units and the relay member,
a pad formed on the other of the corresponding one of the light source units and the relay member and opposed to the bump in the thickness direction, and
an electrically conductive material provided between the bump and the pad.
